(19) United States
(12) Patent Application Publication
(10) Pub. No.: US 2026/0032808 A1
(43) Pub. Date: Jan. 29, 2026

(54) PRINTED CIRCUIT BOARD WITH IMPEDANCE MATCHING THROUGH CONNECTIONS

(71) Applicant: Advanced Micro Devices, Inc., Santa Clara, CA (US)

(72) Inventors: Xuming HAN, Shanghai (CN); Wei HAN, Suzhou (CN)

(21) Appl. No.: 18/783,169

(22) Filed: Jul. 24, 2024

(51) Int. Cl. H05K 1/02; H05K 1/11; H05K 3/00

(52) U.S. Cl. CPC H05K 1/0251; H05K 1/115; H05K 3/0047; H05K 2201/0776; H05K 2201/09518; H05K 2201/09636; H05K 2201/10378

(57) ABSTRACT

Disclosed herein are a printed circuit board and a method of making a printed circuit board. The printed circuit board includes a top surface having a top metal layer; a bottom surface having a bottom metal layer; a first through hole extending from the top surface to the bottom surface; and a first through connection disposed inside the first through hole and coupled to the top metal layer and the bottom metal layer, the first through connection including a first wall segment and a second wall segment that is separated from the first wall segment along a through direction of the first through hole. The method includes forming a through hole in the printed circuit board; disposing a through connection in the through hole; separating the through connection into a plurality of wall segments; and disposing dielectric columns among the plurality of wall segments.

### TECHNICAL FIELD

Embodiments of the present invention generally relate to a printed circuit board, and, more particularly, relate to a printed circuit board having segmented through connections.

### BACKGROUND

An integrated circuit (IC) device is often mounted on a printed circuit board (PCB) for connections to other devices. With the development of the artificial intelligence (AI) technology, more and more printed circuit boards in AI applications hit signal-integrity problems because high-speed signals can be reflected or distorted when high-speed signals see changes of impedance along a long transmission line in the printed circuit board. Signal integrity may be generally understood to the problems that arise in high-speed products due to discontinuity of impedances across an interconnecting interface. A low signal integrity can change the voltage and waveform of a digital signal and change the timing for the signal to reach a receiver.

In a multi-layer PCB, signals are often transmitted among different routing layers that are coupled via through connections (TC). As a TC has a different dimension from the routing layers, a TC often behaves like a breaking point that has an abrupt change of the impedance regarding the high-speed signal. The discontinuous impedance between a signal line and a TC can cause signal reflection and attenuation, in particular in a high speed data transmission.

Conventional technologies for increasing the signal integrity is achieved by matching impedance along a transmission line of a PCB. The conventional matching method involves a systematic design of transmission lines to have a specific material, length, width, and thickness. But, it lacks the flexibility to readjusting impedance of the transmission lines after the PCB is made. The effects of the impedance matching may also be limited by the TC whose dimensions are also subject to other requirements.

Therefore, a need exists for a printed circuit board with an improve impedance matching configuration along a signal transmission line.

### SUMMARY

Disclosed herein are a printed circuit board and a method of making a printed circuit board. In an example, the printed circuit board includes a top surface having a top metal layer; a bottom surface having a bottom metal layer; a first through hole extending from the top surface to the bottom surface; and a first through connection disposed inside the first through hole and coupled to the top metal layer and the bottom metal layer, the first through connection including a first wall segment and a second wall segment that is separated from the first wall segment along a through direction of the first through hole.

In various examples, the first through connection includes a third wall segment separated from the first wall segment and the second wall segment along the through direction of the first through hole. The first wall segment and the second wall segment have an annular shape and are concentric. The through connection includes a first dielectric column disposed between the first wall segment and the second wall segment. The first dielectric column has a circular shape and is non-concentric with the first wall segment. The through connection may further include a second dielectric column disposed between the first wall segment and the second wall segment. The first dielectric column and the second dielectric column contact an inner perimeter of the first through hole. The first dielectric column and the second dielectric column separate the first wall segment and the second wall segment into equal sizes or different sizes. A third dielectric column may be disposed between and being concentric with the first wall segment and the second wall segment.

In yet other examples, the first wall segment is coupled to a high speed data line, and the second wall segment is coupled to a ground signal line. The printed circuit board includes a second through hole extending from the top surface to the bottom surface; and a second through connection disposed inside the second through hole and coupled to the top metal layer and the bottom metal layer, the second through connection comprising a third wall segment and a fourth wall segment that is separated from the third wall segment along a through direction of the second through hole. The second wall segment and the third wall segment are coupled to a high speed data line, and the first wall segment and the forth wall segment are coupled to a ground signal line.

In another example, the method includes forming a through hole in the printed circuit board; disposing a through connection in the through hole; separating the through connection into a plurality of wall segments; and disposing dielectric columns among the plurality of wall segments. The size of a wall segment is determined based on the impedance value of a transmission path to which the wall segment belongs. The plurality of wall segments of a through hole can have different sizes.

In various examples, the method may further includes coupling one of the plurality of the wall segments to a high speed data line; and coupling another one of the plurality of the wall segments to a ground signal line. Disposing a through connection may be implemented by plating a metal layer in the through hole. Separating the through connection may be implemented by drilling through the metal layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic cross-sectional view of an integrated circuit die assembly with an interposer, according to an embodiment of the present disclosure.

FIG. 2 illustrates a schematic partial cross-sectional view of a printed circuit board having a through connection, according to an embodiment of the present disclosure.

FIG. 3A illustrates a schematic top view of a through connection of a printed circuit board, according to an embodiment of the present disclosure.

FIG. 3B illustrates a schematic top view of a through connection of a printed circuit board, according to an embodiment of the present disclosure.

FIG. 4 illustrates a schematic cross-sectional view of a through connection of a printed circuit board, according to an embodiment of the present disclosure.

FIG. 5 illustrates a schematic top view of a through connection having more than two separated conductors, according to an embodiment of the present disclosure.

FIG. 6 illustrates a method for making a printed circuit board, according to an embodiment of the present disclosure.

FIG. 7 illustrates a method of forming a printed circuit board, according to an embodiment of the present disclosure.

To facilitate understanding, identical reference numerals have been used, where possible, to designate identical elements that are common to the figures. It is contemplated that elements of one embodiment may be beneficially incorporated in other embodiments.

### DETAILED DESCRIPTION

In an example, a printed circuit board as set forth in various embodiments of the present disclosure includes a through connection disposed in a through hole. The through connection is formed by a plurality of separated wall segments. Each of the wall segment is connected to a data signal line or a ground signal line. The separation of the wall segments is formed after a contiguous metal layer is plated in the through hole. Drilling, cutting or etching may be used to separate the contiguous metal layer into a plurality of wall segments. The separation of the wall segment is along a through direction of the through hole. The location of the separation is determined to separate the contiguous metal layer into different segments having predetermined impedances for matching with a transmission line. The separation may be filled with a dielectric material to reduce signal interference transmitted along two adjacent wall segments.

The printed circuit board and the method for forming the printed circuit board as set forth in the present disclosure allow an improved impedance matching between the through connection and the transmission line even after the metal layer is plated in the through hole. In this manner, signal reflection by a through connection is reduced, and signal integrity is enhanced.

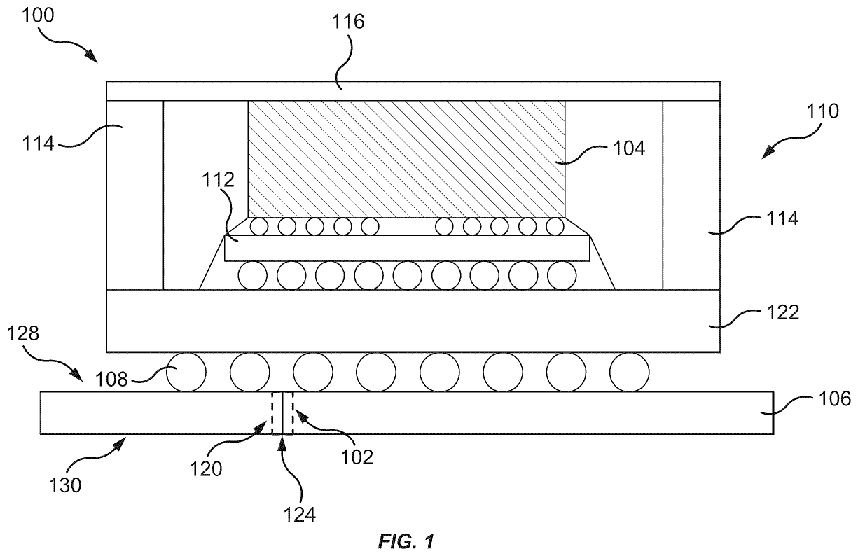

FIG. 1 illustrates a schematic cross-sectional view of an electronic device 100, according to an embodiment of the present disclosure. The electronic device 100 may be included in a tablet, computer, copier, digital camera, smart phone, control system, automated teller machine, server, a data center, an artificial intelligence (AI) engine, or other solid-state memory and/or logic device. The electronic device 100 includes a chip assembly 110 mounted on a printed circuit board (PCB) 106 as set forth in various embodiments of the present disclosure. The chip assembly 110 is connected with the PCB 106 via a plurality of electrical connections 108, such as solder balls or other suitable connections. The electronic device 100 may include one or more PCBs 106, and the PCB 106 may include one or more chip assemblies 110.

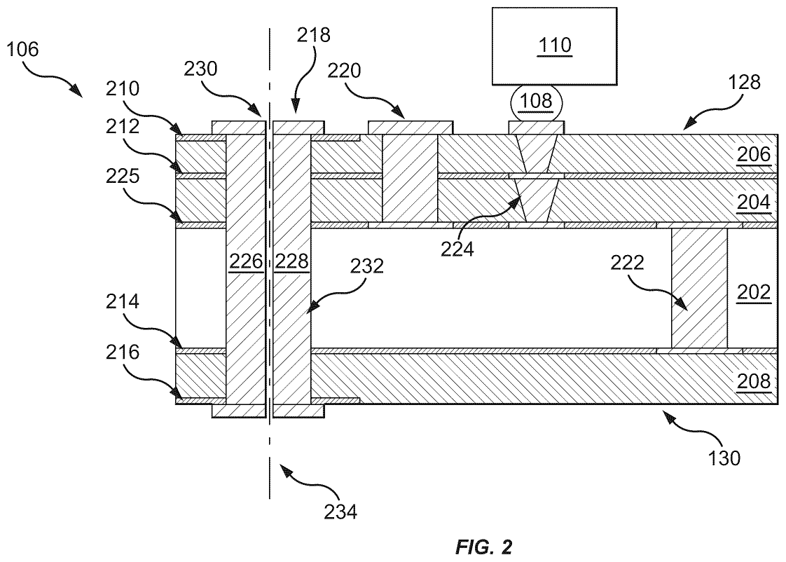

The PCB 106 has a component side 128 on which a plurality of electric components, such as the chip assembly 110, are mounted. The component side 138 is also known as the top side. The PCB 106 also has a back side 130, which is opposite to the component side 128 and has a plurality of solders (not shown). The back side 130 may also have electric components mounted thereof. The back side 130 is also known as the bottom side. In an embodiment, the PCB 106 has a through connection 102 formed by a plurality of separated wall segments 124, later detailed in FIG. 2. The wall segments of the through connections 102 may be made of a metal, such as copper, aluminum, solder, or any other suitable conductive material. The through connection 102 extends from the component side 128 to the back side 130. The PCB 106 may include more than one through connections 102. The through connections 102 are disposed inside through holes 120. The wall segments of the through connections 102 may be plated in the through hole 120 or disposed in the through hole 120 by any other suitable method.

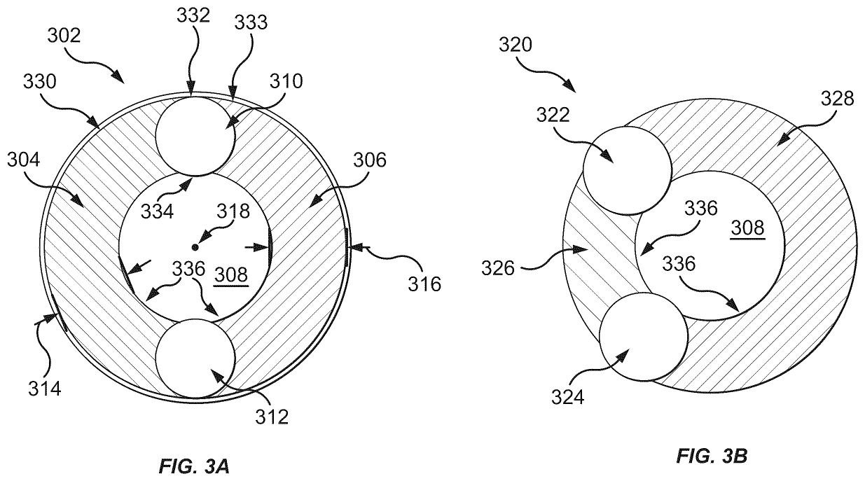

The through hole 120 may have various sizes and shapes depending on the applications and classifications of a PCB. For example, the diameter of a round through hole 120 of a PCB may range from about 0.20 mm to about 1 mm. The thickness (shown as 314 in FIG. 3A) of the wall segment or the through connection 102 disposed in the through hole 120 may range from about 20 μm to about 40 μm. A through-hole 120 may have a shape of square, round, octagon, or any other shape. A more detailed description of the PCB 106 and the through connection 102 will be provided later with reference to other figures of the present disclosure.

The chip assembly 110 further includes an IC die stack 104 mounted on an interposer 112. The interposer 112 couples the IC die stack 104 with a package substrate 122 and provides data communication and power transmission between the IC die stack 104 and the package substrate 122. The chip assembly 110 further includes an optional stiffener 114 coupled with the package substrate 122 and configured to enhance the warpage resistance of the package substrate 122 against out of plane deformation. The chip assembly 110 further includes a lid 116 configured to cover the IC die stack 104 and dissipate heat generated by the chip assembly 110.

FIG. 2 illustrates a schematic partial cross-sectional view of a printed circuit board 106 having a through connection, according to an embodiment of the present disclosure. The PCB 106 includes a core 202, a plurality of upper dielectric layers 204, 206, a plurality of upper metal traces 210, 212, 225, a plurality of lower dielectric layers 208, and a plurality of lower metal traces 214, 216. The core 202 may be made of a dielectric material, a composite material, a metal, or any other suitable material which has sufficient mechanical integrity to support the metal traces and dielectric layers to be disposed on the two sides of the core 202. The core 202 may be rigid.

The plurality of the upper metal traces 210, 212, 225, and the upper dielectric layers 204, 206 are disposed on the component side 128 of the core 202 and are configured to couple with the chip assembly 110 via the electrical connection 108. The lower metal traces 214, 216 and the lower dielectric layer 208 are disposed on the back side 130 of the core 202. The PCB 106 is configured to transmit electrical signals, such as power, data, control command, and other signals, from the chip assembly 110 to another electronic device (not shown). The electrical signals may be transmitted via the metal traces of the PCB 106.

The PCB 106 also includes a plurality types of vias or connections 218, 220, 224, and 222. The via 218 functions as a through connection that connects metal traces 210, 212, 225 of the component side 128 with the metal traces 214, 216 of the back side 130. The via or through connection 218 centers around and extends along a through direction 234 that is substantially perpendicular to the component side 128 and the back side 130. The via 220 functions as an upper blind via disposed in the component side 128. The via 220 extends from the component side 128 to the core 202 and couples with metal traces 210, 212, 225. The via 220 does not extend into the core 202. The via 222 functions as an embedded via disposed in the core 202 and couples a metal trace 225 of the component side with a metal trace 214 of the back side. The via 222 does not extend to the component side 128 and the back side 130. The via 218, 220, and 222 may be disposed by a plating method. The via 224 is formed between adjacent metal traces, such as between the metal trace 225 and 212 and between the metal traces 212 and 210. The via 224 may be formed by a non-plating method, such as thin film deposition, and may have a smaller dimension than the other vias.

The through connection 218 is formed in the through hole 232. The through hole 232 centers around and extends along a through direction 234 that is substantially perpendicular to the component side 128 and the back side 130. In an embodiment, the through connection 218 includes a plurality of separated wall segments 226 and 228, which are isolated by a dielectric column 230. Each of the wall segments 226 and 228 is configured to provide an electrical connection among the metal traces disposed on both sides of the PCB 106. For example, the wall segment 226 extends from the component side 128 to the back side 130 and couples with the metal traces 210, 212, 225, 214, and 216. The wall segment 228 also extends from the component side 138 to the back side 130 and couples with the metal traces 210, 212, 225, 214, and 216. The wall segments 226 and 228 are not required to couple with all metal traces and may be selectively coupled to metal traces at predetermined layers. For example, the wall segments 226 and 228 may be coupled only with the top metal trace 210 and the bottom metal trace 216.

In an embodiment, one or more dielectric columns 230 are disposed at predetermined locations in the through hole 232 or around an inner perimeter of the through hole 232. The dielectric columns 230 extends from the component side 128 to the back side 130 to separate the wall segments 226 and 228 into predetermined sizes. As a result, the impedance of the through connection 218 may be adjusted by separating the wall segments 226, 228 by the dielectric column 230. In an embodiment, two, three, or more dielectric columns 230 may be used to separate the through connection 218 into three, four, or even more wall segments to control the impedance of the through connection 218. The dielectric column 230 may be made of any dielectric material, such as air, epoxy, polytetrafluoroethylene (PTFE), polyimide, or any other suitable material. The dielectric column 230 may have any suitable shape, such as a circle, a rectangle, and a slit.

In an embodiment, a single through connection 218 is configured to transmit a plurality of signals of different types. As the single through connection 218 has a plurality of isolated wall segments, each wall segment may transmit a certain type of a signal. For example, the wall segment 226 may be utilized to transmit an input signal, while the wall segment 228 may be utilized to transmit a return or ground signal.

FIG. 3A illustrates a schematic top view of a through connection 302, according to an embodiment of the present disclosure. The through connection 302 is disposed in a through hole 330 that can be used in the PCB 106 illustrated in FIG. 1. In an embodiment, the through hole 330 and the through connection 302 are substantially circular and have a common center 318. The through connection 302 can be plated in the through hole 330 or disposed by any other suitable method. The through connection 302 includes a pair of wall segments 304 and 306 that are separated by two dielectric columns 310 and 312. The wall segment 304 has an annular shape having a thickness 314. The wall segment 304 also has annular shape having a thickness of 316. The two wall segments 304 and 306 are concentric with the through hole 330. As the wall segments 304 and 306 are made by a same plating process, their thicknesses 314 and 316 are substantially identical. The thickness 314 or 316 may be between about 10 μm to about 40 μm. In the example of FIG. 3A, the two dielectric columns 310 and 312 separate the wall segment 304 and the wall segment 306 into substantially equal sizes.

The two dielectric columns 310 and 312 may be formed by drilling, milling, ablating, cutting or other suitable technique after the through connection 302 is disposed in the through hole 330. In an example, the through connection 302 is first plated in the through hole 330 and has a complete annular shape. Then, two gaps or slits may be formed in the through connection 302 by milling, ablating, cutting or other suitable technique to form two separated circular segments, such as the wall segments 304, 306. The dielectric columns 310 and 312 may be made of any dielectric material, such as air, epoxy, polytetrafluoroethylene (PTFE), polyimide, or any other suitable material. For separation, the two dielectric columns 310, 312 have a thickness that is greater than the thickness 314, 316 of the wall segments 304, 306. In an embodiment, the dielectric columns 310, 312 are circular with a diameter greater than the thickness 314, 316. For example, one side 332 of the dielectric column 310 contacts an inner perimeter 333 of the through hole 330, while the other side 334 of the dielectric column 310 extends beyond the inner circumference 336 of the wall segment 304, 306. The dielectric columns 310 and 312 may have a circular shape, a rectangle shape, or a slit shape.

The through connection 302 may also include a dielectric core 308 that is disposed around the center 318. The dielectric core 308 separates the wall segments 304 and 306 and contacts with the dielectric column 310 and 312. The dielectric core 308 may be made of any dielectric material, such as air, epoxy, polytetrafluoroethylene (PTFE), polyimide, or any other suitable material. The dielectric core 308 can further reduce any signal interference among signals transmitted along the wall segments 304 and 306.

In an embodiment, the through connection 302 may be configured to transmit a plurality of signals of different types. As the through connection 302 has two isolated wall segments, each wall segment may transmit a certain type of signals. For example, the wall segment 304 may be utilized to transmit an input signal, which may be positively charged, while the wall segment 306 may be utilized to transmit a ground signal, which may be negatively charged.

FIG. 3B illustrates a schematic top view of a through connection 320, according to an embodiment of the present disclosure. The through connection 320 can be used in the PCB 106 illustrated in FIG. 1. Comparing to the through connection 302, the through connection 320 includes two differently sized wall segments 326 and 328. When the two dielectric columns 322, 324 are formed at various locations along the inner perimeter 333 of the through hole 330, the sizes of the wall segments 326, 328 can be adjusted, which allows the adjustment of their impedance after they were disposed in the through hole 330. In the example shown in FIG. 3B, the wall segment 326 may be used to transmit a signal that requires a smaller impedance than the signal transmitted along the wall segment 328. The sizes of the wall segment 326 and 328 can be determined according to impedance values required by their respective transmission path.

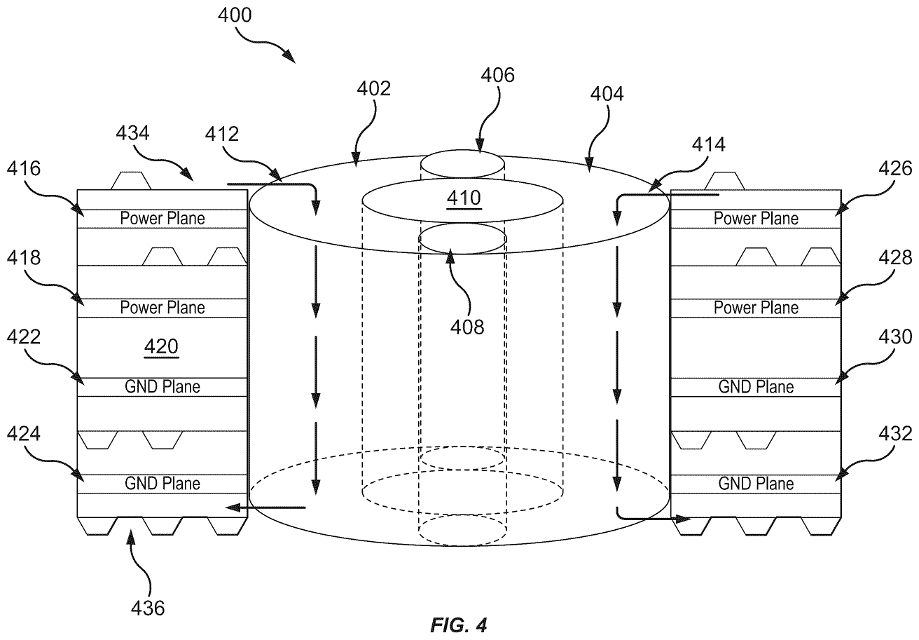

FIG. 4 illustrates a schematic cross-sectional view of a through connection 400 coupling with a plurality of transmission lines, according to an embodiment of the present disclosure. The through connection 400 can be used in the PCB 106 illustrated in FIG. 1. The through connection 400 includes a pair of wall segments 402, 404 separated by a pair of dielectric columns 406, 408, all of which extend from a component side 434 to a back side 436. A dielectric core 410 may be formed by filling the center of the through connection 400 with a dielectric material.

In an embodiment, the wall segment 402 transmits a high speed data signal 412 among a plurality of transmission lines, such as four (4) metal layers in a PCB. Examples of a high speed data signals 412 include data signals transmitted according to standards PCIe 4.0/5.0, USB 3.0/3.1/3.2/4.0, DDR5 DQ, DDR5 DQS, and DDR5 CLK. To transmit these high speed data signals with a high signal integrity along the transmission line, the impedance of the wall segment 402 may range from about 40 Ohm to about 85 Ohm. The wall segment 404 transmits a ground signal 414 among the plurality of transmission lines. At the side for transmitting the high speed data signal 412, the four (4) mental layers include two power planes 416, 418 and two ground planes 422, 424 connected with the wall segments 402. At the side for transmitting the ground signal 414, the four (4) mental layers include two power planes 426, 428 and two ground planes 430, 432 connected with the wall segments 404. When the high speed data signal 412 is transmitted close to the ground signal 414 in the through connection 400, the integrity of the signals can also be improved.

In FIG. 4, the power plane 416, 426 may be understood as the top metal layer disposed on the surface of the component side 434. The ground plane 424, 432 may be understood as the bottom metal layer disposed on the surface of the back side 436.

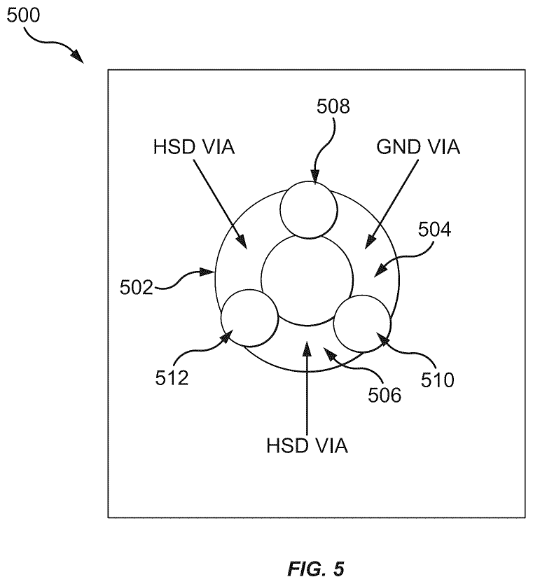

FIG. 5 illustrates a schematic top view of a through connection 500 having three wall segments, according to an embodiment of the present disclosure. The through connection 500 can be used in the PCB 106 illustrated in FIG. 1. The through connection 500 includes three wall segments 502, 504, 506 separated by three dielectric columns 508, 510, 512. Two of the wall segments 502, 506 may be used to transmit high speed data signals, and the wall segment 504 may be used to transmit the ground signal. In an example, the wall segment 502 transmits a first high speed signal that complies with a first standard, while the wall segment 504 transmits a second high speed signal that complies with a second standard different from the first standard. The present disclosure is not limited to two or three separated wall segments in a through connection, but could have four, five, or even greater number of separated wall segments in a through connection. Each through connection may have more than one wall segments for transmitting high speed data signals and more than one wall segments for transmitting the ground signal.

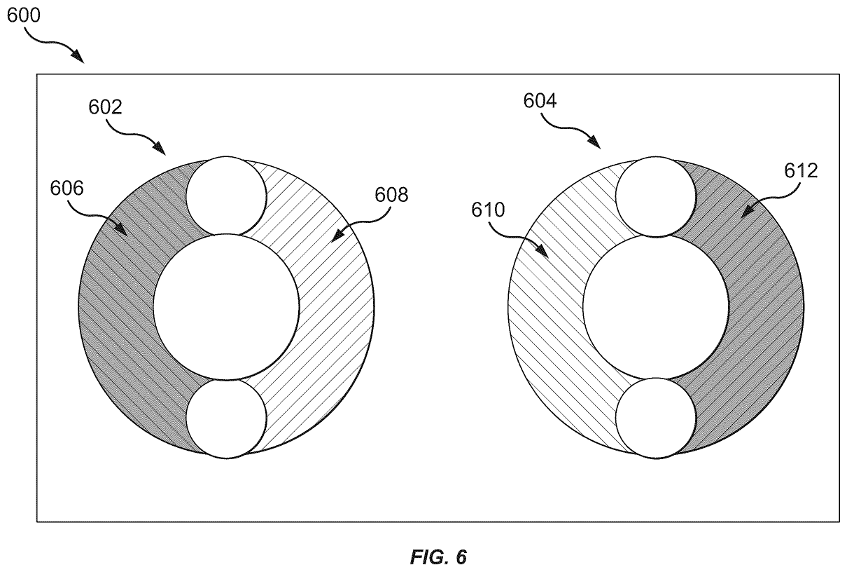

FIG. 6 illustrates a schematic partial top view of a PCB 600 having a pair of through connections, according to an embodiment of the present disclosure. The PCB 600 includes two through connections 602 and 604 disposed next to each other. The through connections 602 and 604 include a plurality of wall segments 606, 608, 610, and 612, which can be arranged in many configurations for transmitting signals. For example, each wall segment may be configured to transmit a positive signal or a negative signal.

In an embodiment, signals transmitted by the wall segments 606, 608, 610, and 612 are arranged to reduce interferences. For example, the wall segment 606 may transmit a high speed data signal and the wall segment 608 may transmit a ground signal. Similarly, the wall segment 612 may also transmits a high speed data signal and the wall segment 610 may transmit a ground signal. To improve signal integrity, the two wall segments 608 and 610, which are used to transmit the ground signals, are disposed adjacent to each other. In other words, the wall segments 608, 610 are disposed between the two wall segments 606 and 612 for transmitting the high speed data signals. This arrangement of the two of the through connections 602 and 604 can reduce potential interference between the two high speed data signals.

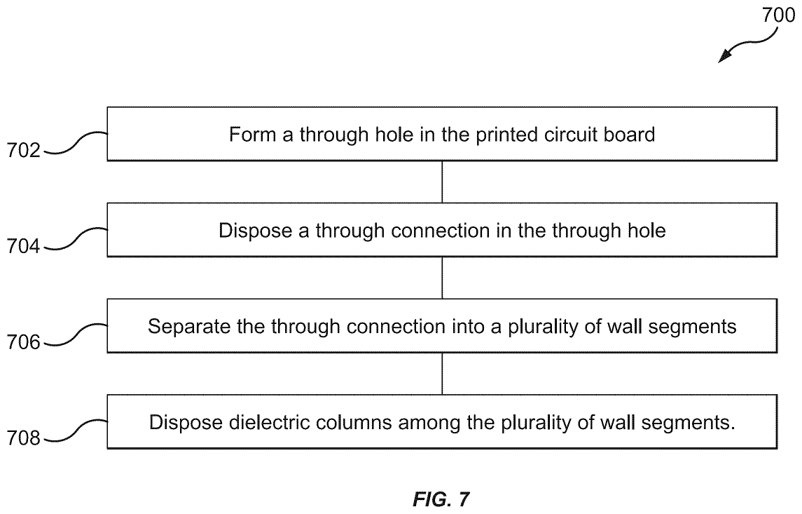

FIG. 7 illustrates a method of forming a printed circuit board, according to an embodiment of the present disclosure. The method 700 starts with an unfinished printed circuit board, which has metal layers and dielectric layers formed on a core. At operation 702, a plurality through holes are formed in the printed circuit board by drilling, puncturing, etching, or any other suitable method. The through holes may have a circular shape with a diameter of about 0.20 mm to about 1 mm. At operation 704, a through connection is formed in the through hole. The through connection formed by a metal layer is disposed in the through hole by plating or any other suitable methods. The metal layer may have an annular shape having a hollow center. The metal layer may have a thickness between about 10 μm to about 40 μm. At operation 706, the metal layer is separated into a plurality of wall segments, such as two, three or greater number of wall segments. The separation is along the through direction of the through hole and may be formed by drilling, milling, ablating, cutting, or any other suitable method. At operation 708, dielectric columns may be formed by filling the separations with dielectric materials. The method 700 may further include determining a size of a wall segment based on the impedance value required by a transmission path to which the wall segment belongs. The method 700 may further include coupling one of the plurality of the wall segments to a high speed data line; and coupling another one of the plurality of the wall segments to a ground signal line.

The present disclosure provides an improved printed circuit board having a new configuration of a through connection. The printed circuit board includes a top surface having a top metal layer; a bottom surface having a bottom metal layer; a first through hole extending from the top surface to the bottom surface; and a first through connection disposed inside the first through hole and coupled to the top metal layer and the bottom metal layer, the first through connection including a first wall segment and a second wall segment that is separated from the first wall segment along a through direction of the first through hole.

In various examples, the first through connection includes a third wall segment separated from the first wall segment and the second wall segment along the through direction of the first through hole. The first wall segment and the second wall segment have an annular shape and are concentric. The through connection includes a first dielectric column disposed between the first wall segment and the second wall segment. The first dielectric column has a circular shape and is non-concentric with the first wall segment. The through connection may further include a second dielectric column disposed between the first wall segment and the second wall segment. The first dielectric column and the second dielectric column contact an inner perimeter of the first through hole. The first dielectric column and the second dielectric column separate the first wall segment and the second wall segment into equal sizes. A third dielectric column may be disposed between and being concentric with the first wall segment and the second wall segment.

In yet other examples, the first wall segment is coupled to a high speed data line, and the second wall segment is coupled to a ground signal line. The printed circuit board includes a second through hole extending from the top surface to the bottom surface; and a second through connection disposed inside the second through hole and coupled to the top metal layer and the bottom metal layer, the second through connection comprising a third wall segment and a fourth wall segment that is separated from the third wall segment along a through direction of the second through hole. The second wall segment and the third wall segment are coupled to a high speed data line, and the first wall segment and the forth wall segment are coupled to a ground signal line.

The present disclosure also provides a method for making a printed circuit board. The method includes forming a through hole in the printed circuit board; disposing a through connection in the through hole; separating the through connection into a plurality of wall segments; and disposing dielectric columns among the plurality of wall segments.

In various examples, the method may further includes coupling one of the plurality of the wall segments to a high speed data line; and coupling another one of the plurality of the wall segments to a ground signal line. Disposing a through connection may be implemented by plating a metal layer in the through hole. Separating the through connection may be implemented by drilling through the metal layer.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, within a range includes every point or individual value between its end points even though not explicitly recited. Thus, every point or individual value may serve as its own lower or upper limit combined with any other point or individual value or any other lower or upper limit, to recite a range not explicitly recited.

All numerical values within the detailed description herein are modified by “about” the indicated value, and take into account experimental error and variations that would be expected by a person having ordinary skill in the art.

As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including.” Likewise whenever a composition, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa.

While the foregoing is directed to embodiments of the present invention, other and further embodiments of the invention may be devised without departing from the basic scope thereof, and the scope thereof is determined by the claims that follow.

What is claimed is:

1. A printed circuit board comprising:
a top surface having a top metal layer;
a bottom surface having a bottom metal layer;
a first through hole extending from the top surface to the bottom surface; and
a first through connection disposed inside the first through hole and coupled to the top metal layer and the bottom metal layer, the first through connection comprising a first wall segment and a second wall segment that is separated from the first wall segment along a through direction of the first through hole.

2. The printed circuit board of claim 1, wherein the first through connection comprises a third wall segment separated from the first wall segment and the second wall segment along the through direction of the first through hole.

3. The printed circuit board of claim 1, wherein the first wall segment and the second wall segment have an annular shape and are concentric.

4. The printed circuit board of claim 3, further comprising a first dielectric column disposed between the first wall segment and the second wall segment.

5. The printed circuit board of claim 4, wherein the first dielectric column has a circular shape and is non-concentric with the first wall segment.

6. The printed circuit board of claim 4, further comprising a second dielectric column disposed between the first wall segment and the second wall segment.

7. The printed circuit board of claim 6, wherein the first dielectric column and the second dielectric column contact an inner perimeter of the first through hole.

8. The printed circuit board of claim 7, wherein the first wall segment and the second wall segment have different sizes.

9. The printed circuit board of claim 8, further comprising a third dielectric column disposed between and being concentric with the first wall segment and the second wall segment.

10. The printed circuit board of claim 9, wherein the first wall segment is coupled to a high speed data line.

11. The printed circuit board of claim 10, wherein the second wall segment is coupled to a ground signal line.

12. The printed circuit board of claim 1, further comprising:
a second through hole extending from the top surface to the bottom surface; and
a second through connection disposed inside the second through hole and coupled to the top metal layer and the bottom metal layer, the second through connection comprising a third wall segment and a fourth wall segment that is separated from the third wall segment along a through direction of the second through hole,
wherein the second wall segment and the third wall segment are coupled to a high speed data line, and the first wall segment and the fourth wall segment are coupled to a ground signal line.

13. The printed circuit board of claim 12, wherein the second wall segment and the third wall segment are disposed between the first wall segment and the fourth wall segment.

14. The printed circuit board of claim 13, wherein the second wall segment and the third wall segment are connected to a ground signal line.

15. The printed circuit board of claim 11, wherein the first through connection further comprises at least three separated wall segments.

16. The printed circuit board of claim 15, wherein the first through connection further comprises at least three dielectric columns separating the at least three wall segments.

17. A method of making a printed circuit board, comprising:
forming a through hole in the printed circuit board;
disposing a through connection in the through hole;
separating the through connection into a plurality of wall segments; and
disposing dielectric columns among the plurality of wall segments.

18. The method of claim 17, further comprising:
coupling one of the plurality of the wall segments to a high speed data line; and
coupling another one of the plurality of the wall segments to a ground signal line.

19. The method of claim 18, wherein disposing the through connection comprises plating a metal layer in the through hole.

20. The method of claim 19, wherein separating the through connection comprises drilling through the metal layer.
